(19) United States
(12) Patent Application Publication
(10) Pub. No.: US 2009/0014897 A1
(43) Pub. Date: Jan. 15, 2009

(54) Semiconductor chip package and method of manufacturing the same

(75) Inventor: Yasuhide Ohno, Kumamoto-shi (JP)

Correspondence Address: OLIFF & BERRIDGE, PLC, P.O. BOX 320850, ALEXANDRIA, VA, 22320-4850, US

(73) Assignee: Kumamoto Technology & Industry Foundation, Kumamoto (JP)

(21) Appl. No.: 12/219,211

(22) Filed: Jul. 17, 2008

Related U.S. Application Data
(63) Continuation-in-part of application No. 10/556,335, filed on Nov. 10, 2005, now abandoned.

(30) Foreign Application Priority Data
May 15, 2003 (JP) 2003-137140
May 12, 2004 (JP) 2004-141893

(51) Int. Cl. H01L 23/52; H01L 21/00

(52) U.S. Cl. 257/778; 438/108; 257/E23.141; 257/E21.001

(57) ABSTRACT

A semiconductor chip (20) including a protruding electrode (bump) (23) in an external extraction electrode is mounted on a wiring board (10), and a semiconductor chip (30) is mounted on the semiconductor chip (20). Electrical connections between a wiring layer (12) of the wiring board (10) and the protruding electrode (23) of the semiconductor chip (20) and between the protruding electrodes of the semiconductor chips (20) and (30) are established by electrolytic plating. Stable connections between the wiring layer (12) and the protruding electrode (23) and between the protruding electrodes of the semiconductor chips (20) and (30) are established by plating films (24) and (33).

This is a Continuation-In-Part of U.S. patent application Ser. No. 10/556,335, filed Nov. 10, 2005, which in turn is a National Stage of PCT/JP2004/006878, filed May 14, 2004, which in turn claims the benefit of Japanese Patent Application Nos. 2003-137140, filed May 15, 2003 and 2004-141893, filed May 12, 2004. The entire disclosures of the prior applications are hereby incorporated by reference herein in their entirety.

### TECHNICAL FIELD

The present invention relates to a semiconductor chip package in which a plurality of semiconductor chips are connected by flip chip bonding, and a method of manufacturing the semiconductor chip package.

### BACKGROUND ART

In response to a social demand for a reduction in the size and weight of electronic devices, semiconductor devices such as LSIs (Large Scale Integrated circuits) are becoming smaller and denser. As one of techniques for making the semiconductor devices smaller and denser, a technique of stacking semiconductor chips is used.

Conventionally, as shown in FIG. 2, such a technique of stacking semiconductor chips is performed through mounting a small semiconductor chip 102 on a large semiconductor chip 101 mounted on a wiring board 100 by an adhesive or the like, establishing an electrical connection between the wiring board 100 and the semiconductor chips 101 and 102 by a bonding wire 103, and then sealing them in a resin. In order to make the semiconductor devices ever smaller and denser, it is necessary to reduce the size and the profile of each semiconductor chip.

However, a semiconductor chip package formed through stacking semiconductor chips by the above-described method has the following disadvantages. First, the semiconductor chip 101 and a board electrode on the wiring board 100 are electrically connected to each other by the bonding wire 103, so the bonding wire 103 acts as an inductance specifically in high-frequency operation, thereby the bonding wire 103 becomes a factor which interferes with smooth operation. Moreover, there is a disadvantage that the profile of each semiconductor chip cannot be sufficiently reduced, because the bonding wire 103 protrudes from a top surface of each of the semiconductor chips 101 and 102, and it is necessary to secure a region for wire bonding. Further, a gold wire is typically used as the bonding wire 103, so it becomes a factor contributing to an increase in cost. In addition, in wire bonding, a load applied to the semiconductor chip 101 stacked in a lower stage is large during bonding, thereby the thin semiconductor chip 101 may be damaged.

For these reasons, as an alternative to wire bonding, a CSP (Chip Size Package) in which the following semiconductor chips are connected by flip chip bonding has been proposed recently (refer to Japanese Unexamined Patent Application Publication Nos. 2002-203874, 2002-170919, H10-135272, 2001-338949 and H7-263493). In flip chip bonding, unlike the above-described wire bonding, a connection can be established through the use of the whole surfaces of the semiconductor chips, and a connection is established by a protruding electrode (bump), so very small chips can be bonded, and chips can be packaged with high density. However, the CSP has the following disadvantages.

For example, in Japanese Unexamined Patent Application Publication Nos. 2002-203874, 2002-170919 and H10-135272, after a semiconductor chip to be stacked and a wiring board are aligned to be bonded by solder, another semiconductor chip to be stacked is aligned to be bonded by solder. Thus, in the case where solder is used as an electrical adhesive, an effect of self-alignment cannot be expected in batch reflow soldering at the time of multilayer stacking, so semiconductor chips are bonded by solder on a one-by-one basis. However, there are concerns that in this case, heat generated by several solder bonding processes is applied to a bonding portion formed by a first stacking step until a final stacking step, so the structure of a bonding portion in a first stage is different from that in a final stage, and reliability declines due to repeated application of heat.

On the other hand, in Japanese Unexamined Patent Application Publication Nos. 2001-338949 and H7-263493, a semiconductor chip and a wiring board are electrically bonded to each other through the use of a conductive adhesive. However, the conductive adhesive is inferior in terms of conductivity, and has low bonding strength, so in semiconductors which change with time, electrical properties may decline with years of use.

### DISCLOSURE OF THE INVENTION

In view of the foregoing, it is a first object of the invention to provide a semiconductor chip package capable of high density packaging, and having uniform electrical connections between a protruding electrode of a semiconductor chip and a wiring layer of a wiring board and between protruding electrodes of semiconductor chips, and having high reliability.

It is a second object of the invention to provide a method of manufacturing a semiconductor chip package capable of easily manufacturing the above-described semiconductor chip package with high reliability and high density at low cost.

A semiconductor chip package according to the invention comprises: a wiring board including a wiring layer on a surface; a first semiconductor chip including a protruding electrode and being mounted on the wiring board, the first semiconductor chip in which the protruding electrode is in contact with the wiring layer, and the protruding electrode and the wiring layer are electrically connected to each other by plating; and one or two or more second semiconductor chips each including a protruding electrode and being mounted on the first semiconductor chip, the second semiconductor chips in which the protruding electrodes facing each other are electrically connected to each other by plating.

The plating film is made of, for example, copper (Cu), nickel (Ni), gold (Au), tin (Sn) or an alloy thereof.

As the semiconductor chip package according to the invention, it is preferable that the semiconductor chip includes a through electrode formed by filling a through hole penetrating between both surfaces of the semiconductor chip with a conductive material, and an external extraction electrode in an end portion of the through electrode, and the protruding electrode is formed on the external extraction electrode. Moreover, it is preferable that the second semiconductor chips and the wiring board each include a through electrode in a position facing the through electrode of the first semiconductor chip, and the plurality of through electrodes are electrically connected by the protruding electrode, thereby an electrical connecting portion is linearly aligned.

A method of manufacturing a semiconductor chip package according to the invention comprises the steps of: aligning a first semiconductor chip including a protruding electrode with a surface of a wiring board including a wiring layer on the surface so that the protruding electrode is in contact with a connecting point on the wiring layer of the wiring board, and aligning one or two or more second semiconductor chips each including an protruding electrode with the first semiconductor chip so that the protruding electrodes are in contact with one another; and establishing electrical connections between the protruding electrode of the first semiconductor chip and a connecting point of the wiring layer of the wiring board and between the protruding electrodes of the first semiconductor chip and the second semiconductor chips by a plating film.

As a plating method, electroplating or spray plating is preferably used.

At the time of plating, it is preferable that the plating film is formed while supersonic vibration is applied to a wall surface of a plating bath, or after the wiring board on which the first semiconductor chip and the second semiconductor chips are mounted is placed in a plating bath, and a pressure in the plating bath is reduced, a plating solution is contained in the plating bath. Alternatively, the plating film may be formed while applying a pressure to a plating solution contained in the plating bath. By such a method; plating is accelerated, and a stable plating film can be formed.

In the semiconductor chip package and the method of manufacturing a semiconductor chip package according the invention, electrical connections between the protruding electrode of the semiconductor chip and the wiring layer of the wiring board and between the protruding electrodes of the semiconductor chips are established by the plating film, so the plating film is uniformly and stably attached in a bonding point, and a uniform bonding strength can be obtained, and the bonding operation can be performed rapidly, thereby the productivity can be improved. Moreover, as a sufficient space between a lead and a semiconductor chip can be obtained, high integration is possible, so a small semiconductor chip package with extremely high reliability can be provided.

In particular, the semiconductor chip package and the method of manufacturing a semiconductor chip package according to the invention are effective for multilayer connection of semiconductor chips and a wiring board in which very fine wiring of 65 nm or less is included, and the material of an interlayer insulating film under an electrode pad is relatively brittle.

Moreover, in the semiconductor chip package according to the invention, it is preferable that the first semiconductor chip, the second semiconductor chips and the wiring board each have a through electrode, and the through electrodes are electrically connected to one another by a protruding electrode so as to linearly arrange an electrical connecting portion. Thereby, a signal with a frequency of gigahertz (GHz) can be transferred at high speed.

### BRIEF DESCRIPTION OF THE DRAWINGS

FIG. 1 is a sectional view of the structure of a semiconductor chip package according to an embodiment of the invention.

FIG. 2 is a schematic view of a conventional semiconductor chip package.

FIG. 3 is an alternative sectional view of the structure of a semiconductor chip package according to an embodiment of the invention.

### BEST MODE FOR CARRYING OUT THE INVENTION

A preferred embodiment of the invention will be described in detail below referring to the accompanying drawings.

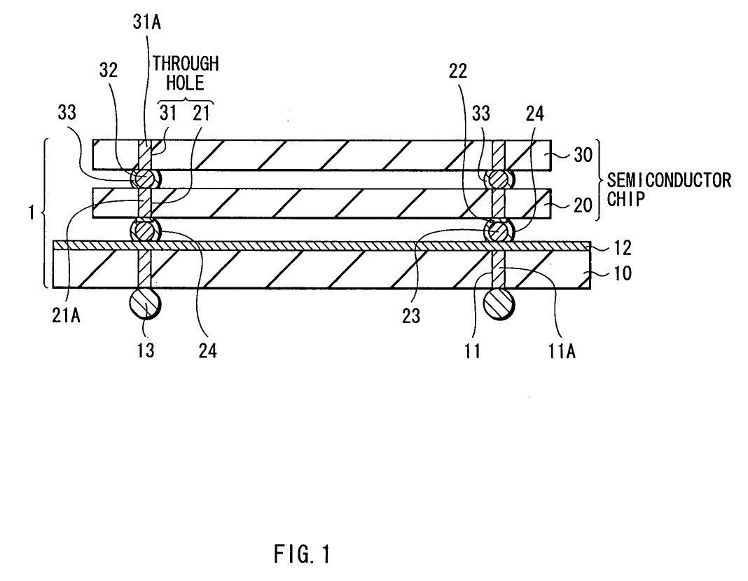

FIG. 1 shows a sectional view of a semiconductor chip package 1 according to an embodiment of the invention. In the semiconductor chip package 1, semiconductor chips 20 and 30 with a multilayer structure (including two layers in this case) are stacked and mounted on a wiring board 10 made of, for example, a polyimide resin.

The wiring board 10 includes a through hole (electrode forming hole) 11, and an electronic circuit is formed on a surface of the wiring board 10 by a wiring layer 12. A through electrode 11A is formed in the electrode forming hole 11. An external electrode 11A can be formed, for example, through plating with nickel (Ni) with a thickness of approximately 1 to 150 μm. As an alternative method, the electrode can be formed through reflowing solder after plating.

A ball electrode 13 made of, for example, solder is formed on a back surface of the wiring board 10 in a position corresponding to the electrode forming hole 11, and the ball electrode 13 and the wiring layer 12 on the front surface are electrically connected to each other by the through hole 11. Further, the ball electrode 13 is electrically connected to an external printed board, although it is not shown.

The wiring board 10 is made of, for example, a polyimide resin, and an electronic circuit on the front surface is formed by a known photolithography technique. In a photolithography method, a board is covered with a resist film, and the resist film is covered with a mask in which a pattern is formed. The whole film as the mask is formed of a photosensitive resin, and the electrode forming hole may be formed by patterning through exposing to light and sensing light. As the resist film, a resin cured by ultraviolet radiation, for example, a photosensitive peeling type acrylic-based resin or an epoxy-acrylic-based resin can be used. The board is covered with the resist film by, for example, a spin coat method, and then patterning of the resist film is carried out by exposure to light and development to form a mask, and the board is etched or plated through the use of the mask, thereby a wiring layer can be formed.

The wiring layer 12 is preferably formed through plating with copper (Cu), because the conductivity is superior. The wiring layer 12 has, for example, a width of approximately 5 to 30 μm.

The lower semiconductor chip 20 (first semiconductor chip) includes a through hole 21, and the through hole 21 is filled with a conductive material, for example, copper (Cu) to form a plug 21A. An external extraction electrode 22 is disposed in a bottom end portion of the plug 21A. A protruding electrode (metal bump) 23 is disposed on a surface of the external extraction electrode 22, and the protruding electrode 23 is in contact with an electrode portion of the wiring layer 12 on a side of the wiring board 10. An area between the external extraction electrode 22 on a side of the semiconductor chip 20 and the wiring layer 12 on a side of the wiring board 10 including the whole surface of the protruding electrode 23 are covered with a conductive plating film 24. The whole protruding electrode 23 and the whole wiring layer 12 are uniformly connected to each other by the plating film 24, thereby poor electrical connection can be prevented.

A wiring pattern (not shown) is formed on a surface of the semiconductor chip 20. The wiring pattern is formed through plating with, for example, molybdenum (Mo), tungsten (W), silicide such as tungsten silicide (WSi₂), or metal with superior conductivity such as gold (Au) or copper (Cu), and then partially removing a metal layer through etching the metal layer by lithography.

The external extraction electrode 22 can be formed, for example, through reflowing a very small solder ball in the through hole 21, or by CVD (Chemical Vapor Deposition) or PVD (Physical Vapor Deposition) such as sputtering.

The protruding electrode 23 is provided to facilitate electrical bonding to the wiring board 10 or another stacked semiconductor, and is formed by, for example, plating. As plating metal, the same kind of metal as plating bonding metal is preferably but not exclusively used, and in consideration of conductivity, adhesion or the like, for example, the plating metal can be selected from the group consisting of copper (Cu), nickel (Ni), gold (Au), tin (Sn) and an alloy thereof. The height of the protruding electrode 23 is preferably 100 μm or less, and specifically within a range from 2 to 50 μm.

The upper semiconductor chip 30 (second semiconductor chip) also includes a through hole 31 in a like manner, and the through hole 31 is filled with, for example, copper (Cu) to form a plug 31A. A protruding electrode (metal bump) 32 is disposed in a bottom end portion of the plug 31A, and the protruding electrode 32 is in contact with the plug 21A in the lower semiconductor chip 20. The surface of the protruding electrode 32 is covered with a plating film 33 made of, for example, nickel (Ni), and an electrical connection between the plug 21A in the semiconductor chip 20 and the plug 31A in the semiconductor chip 30 is secured. The semiconductor chip 30 is the same as the semiconductor chip 20 except for the above-described characteristics.

As the material of the semiconductor chips 20 and 30, for example, germanium (Ge), silicon (Si), gallium arsenide (GaAs), gallium phosphide (GaP) or the like is used, and each chip preferably has as thin a profile as possible so that a packaging product can be downsized. A wafer for such a chip can be manufactured through thinly slicing a single crystal of the above-described material.

Next, a method of manufacturing the above-described semiconductor chip package 1 will be described below. The method includes “an aligning step” and “a bonding step by plating”, and further includes “a resin sealing step” if necessary.

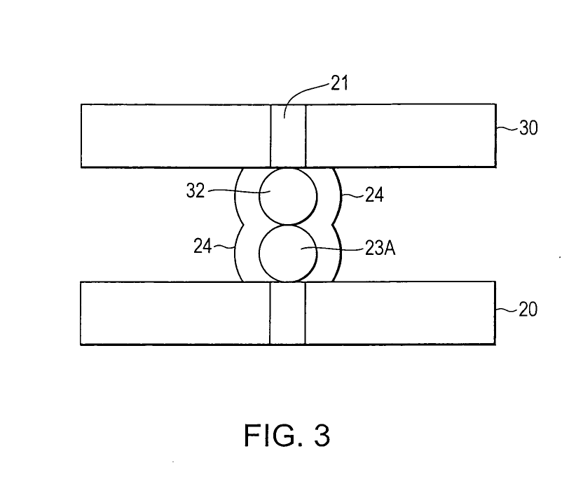

In the aligning step, the semiconductor chip 20 including the protruding electrode 23 is aligned with the surface of the wiring board 11 so that the protruding electrode 23 touches an electrode bonding portion of the wiring layer 12 on the wiring board 11. Next, the second semiconductor chip 30 is aligned with the semiconductor chip 20 so that the protruding electrodes of the semiconductor chips 20 and 30 are in contact with each other. (See protruding electrode 23A of semiconductor chip 20 and protruding electrode 32 of semiconductor chip 30 in FIG. 3.) In addition, in order to prevent an electrical short circuit, an insulating layer such as an insulating film or an insulating paint may be arranged between the semiconductor chips 20 and 30.

An alignment jig made of Teflon (registered trademark) is used for such alignment of the semiconductor chips 20 and 30 and the wiring board 10. The alignment jig includes a protruding portion or a depressed portion for fitting a depressed portion or a protruding portion formed in the wiring board 10 or the semiconductor chips 20 and 30, and the depressed portion or the protruding portion formed in the wiring board 10 or the semiconductor chips 20 and 30 is inserted into the protruding portion or the depressed portion of the alignment jig to perform alignment. An optimum position for alignment is a position in which a current passes, and the current amount is electrically minimized, or the position may be determined by automatic or manual operation while monitoring an image with a microscope.

When the alignment between the wiring board 10 and the semiconductor chip 20 and the alignment between the semiconductor chips 20 and 30 are performed, they are connected by flip chip bonding. More specifically, while two semiconductor chips 20 and 30 and the wiring board 10 are pressed with a jig so as to prevent displacement, plating is performed, thereby the wiring board 10 and the semiconductor chips 20 and 30 are connected by flip chip bonding, that is, electrical connections between the wiring board 10 and the semiconductor chips 20 and 30 are established by the protruding electrodes (bumps).

The plating may be performed through immersing the wiring board 10 and the semiconductor chips 20 and 30 in a plating bath to perform electroplating or electroless plating. Moreover, after contact portions thereof are electrically conducted by a technique such as spraying a plating solution, and then the contact portions may be covered with plating metal to be bonded. Thus, when the plating is performed in such a manner, as shown in FIG. 1, an area between the electrode of the wiring board 10 and the protruding electrode of the semiconductor chip 20 and an area between the protruding electrodes of the semiconductor chips 20 and 30 are covered with plating metal to bond them together. At this time, an oil paint is preferably applied to an electric circuit exposed surface except for a protruding portion which is an electrically bonding point or a contact surface thereof by printing so as to prevent deposition of plating metal.

As metal for plating, for example, copper (Cu), nickel (Ni), gold (Au), tin (Sn) or an alloy thereof can be used, and the same material as that of an electrode such as a protruding electrode may be used, or any other metal may be used.

At the time of the plating, a pressure can be slightly applied between the semiconductor chip 20 and the wiring board 10 to such an extent that the semiconductor chip 20 is not damaged.

In electrolytic plating, the alignment between the electrode of the wiring board 10 and the protruding electrode of the semiconductor chip 20 and the alignment between the protruding electrodes of the semiconductor chips 20 and 30 are performed, and they are immersed in a plating bath. After immersing the wiring board 10 and the semiconductor chips 20 and 30 in the plating bath, a DC voltage is applied between a common electrode as a negative electrode and an electrode for plating as a positive electrode for a predetermined time.

At the time of the plating, supersonic vibration is preferably applied to a liquid wall surface. Thereby, a plating solution can permeate between the wiring board 10 and the semiconductor chip 20 and between the semiconductor chips 20 and 30, and the circulation of the plating solution can be accelerated so that the growth of all bumps by plating can be equalized.

Moreover, a plating film may be formed through placing the wiring board 10 on which the semiconductor chips 20 and 30 are mounted in a plating bath, and reducing a pressure in the plating bath to remove air from narrow areas between the semiconductor chips 20 and 30 and between the wiring board 10 and the semiconductor chip 20, and containing a plating solution in the plating bath. Thereby, the plating solution can sufficiently permeate between the wiring board 10 and the semiconductor chip 20 and between the semiconductor chips 20 and 30, and poor plating in an air-remaining portion can be prevented.

Further, the plating film may be formed while pressurizing air in a surface portion of the plating solution contained in the plating bath. Thereby, the same effect as that described above can be obtained.

After completing the above-described plating step, the plating solution is removed through cleaning with pure water, and a contaminant deposited at the time of plating is removed. Next, if necessary, in order to prevent deterioration due to oxidation or moisture absorption, the wiring board 10 and the semiconductor chips 20 and 30, mainly bonding portions between the wiring board 10 and the semiconductor chips 20 and 30 are partially or thoroughly sealed with a resin. As a sealing resin, a resin with superior electrical insulation and superior heat resistance such as an epoxy resin may be selected.

After the above steps, the board is cut by dicing, a laser beam or the like to be divided, thereby the semiconductor chip package 1 with a high packaging density can be obtained.

Thus, in the embodiment, after the semiconductor chips 20 and 30 are aligned on the wiring board 10, electrical connections between the protruding electrode of the semiconductor chip 20 and the electrode of the wiring board 10 and between the protruding electrodes of the semiconductor chips 20 and 30 are established, so the plating film can be attached uniformly and stably, and a uniform bonding strength can be obtained. Moreover, the bonding operation can be rapidly performed, so productivity is improved. Further, a sufficient space between a lead and a semiconductor chip can be obtained, so high integration is possible, and a small semiconductor chip package with high reliability can be obtained.

In particular, in conventionally used bump connection, a part where the protruding electrodes are not connected (non-bonding part) is microscopically observed in a connecting portion between the protruding electrodes; however, in the embodiment, such a non-bonding part is filled with plating metal, so a sufficient bonding strength can be obtained, and electrical bonding can be sufficiently secured, and the bonding portion has a lower resistance. In particular, when the width of the wiring layer 12 of the wiring board 10 or the width of a wiring layer of the semiconductor chip 20 or 30 is as thin as 65 nm or less, the thickness thereof is also thin, and in the case where an insulating layer under the wiring layer is made of a porous silicon oxide film (SiO₂), the insulating layer is brittle, so it is not preferable to use a conventional technique of applying a pressure such as wiring bonding or bump crimping. In such a case, the technique according to the embodiment is effective, and a semiconductor package including extremely fine wiring with a 10 μm pitch can be obtained without damaging the insulating layer.

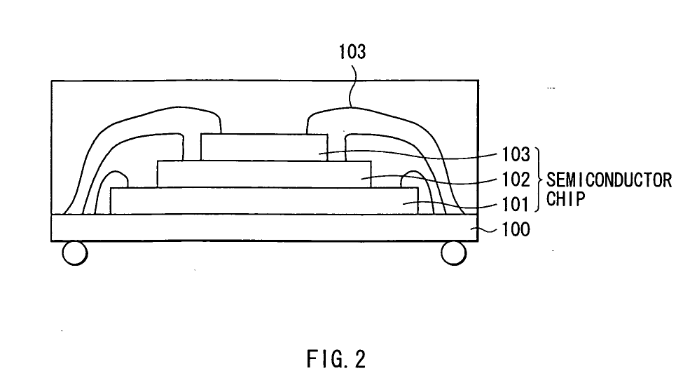

Moreover, it is considered that in future, the transfer of signals with a frequency of gigahertz (GHz) will become widespread; however, when electrodes are connected by a wire as in the case of a conventional device (refer to FIG. 2), a delay in signal transfer develops under the influence of high-frequency resistance caused by the length of the wire and a bend in the wire. On the other hand, in the embodiment, as shown in FIG. 1, the wiring board 10, the semiconductor chip 20 and the semiconductor chip 30 include the through electrode 11A, the through electrode 21A and the through electrode 31A, respectively, and the wiring board 10, the semiconductor chip 20 and the semiconductor chip 30 are disposed so that the through electrodes 11A, 12A and 13A face one another, and the wiring board 10, the semiconductor chip 20 and the semiconductor chip 30 are electrically connected by the protruding electrodes 23 and 32. In other words, the through electrodes 11A, 12A and 13A are linearly connected in the shortest distance, so even a signal with a frequency of gigahertz (GHz) can be stably transferred at high speed.

A specific example will be described below.

In a silicon wafer with a diameter of 4 inches, each chip had a size of 7.5×7.5 mm, and 200 aluminum (Al) electrodes (80 μm×80 μm) were disposed in a peripheral portion of the chip, and the chip except for an electrode portion was covered with a protective film made of a silicon oxide film (SiO₂). Next, a through hole was formed in the electrode portion by a laser, and solder permeated by a capillary phenomenon, and the through hole was filled with the solder. Further, a protruding electrode (bump) made of gold with a height of 5 μm was formed in a solder portion filled with the solder.

Two of the wafers were stacked and aligned so that the protruding electrodes were in contact with each other, and a plated negative electrode was connected to a peripheral portion of the wafers, and the wafers were immersed in a Cu-plating bath (copper sulfate 0.8 mol/l, sulfuric acid 0.5 mol/l) with a current density of 200 A/m², and an area around the protruding electrodes was coated with Cu plating with a thickness of 5 μm so as to establish an electrical connection between the protruding electrodes. Next, a plating solution was removed by cleaning, and an underfill resin was injected into a space between chips. After that, the wafers were divided into chips.

Next, the wiring board and the semiconductor chip were aligned so that an electrode of the wiring board and a protrusion formed in the semiconductor chip by Cu plating touched each other, and then they were fixed with a jig, and the wiring board and two semiconductor chips were connected to one another by plating through the use of the same bath as the above-described plating bath. At that time, the wiring board except for an electrode portion was coated with an oil paint so as to prevent plating.

A semiconductor chip package obtained by the above-described method was cleaned with pure water, and a cleaning solution was dried, thereby a product was obtained.

### (Result of Peel Test)

A shear test was performed on a bonding portion connected by plating, and the interlayer adhesion strength between the semiconductor chips was measured. As a result, an average strength of 10 g/bump was obtained, so it was found out that the bonding portion was extremely good.

### (Electrical Resistance Test)

In an electrical resistance test, a good connection resistance of 0.5 mΩ/bump was shown.

The invention is described referring to the embodiment and the example; however, the invention is not limited to the above-described embodiment and the above-described example, and is variously modified. For example, not only two layers but also three or more layers of semiconductor chips can be mounted on the wiring board 10. In other words, two or more second semiconductor chips may be mounted on the first semiconductor chip on the wiring board 10 in order.

1. A semiconductor chip package, comprising:
a wiring board including a wiring layer on a surface;
a first semiconductor chip including a protruding electrode and being mounted on the wiring board, the protruding electrode being in contact with the wiring layer, and at least an area around a contact portion between the protruding electrode and the wiring layer being covered with a conductive plating film; and
one or two or more second semiconductor chips each including a protruding electrode and being mounted on the first semiconductor chip, the second semiconductor chips having at least an area around a contact portion between protruding electrodes that is covered with a conductive plating film, whereby a sufficient bonding strength can be obtained and electrical bonding can be sufficiently secured between the protruding electrodes.

2. A semiconductor chip package according to claim 1, wherein
the plating film is made of copper (Cu), nickel (Ni), gold (Au), tin (Sn) or an alloy thereof.

3. A semiconductor chip package according to claim 1, wherein
the first semiconductor chip includes a through electrode formed by filling a through hole penetrating between both surfaces of the first semiconductor chip with a conductive material, and an external extraction electrode in an end portion of the through electrode, and the protruding electrode is formed on the external extraction electrode.

4. A semiconductor chip package according to claim 3, wherein
the whole protruding electrode and the whole external extraction electrode in a connecting portion between the wiring board and the first semiconductor chip are covered with the plating film.

5. A semiconductor chip package according to claim 4, wherein
the whole protruding electrodes of the semiconductor chips are covered with the plating film.

6. A semiconductor chip package according to claim 1, wherein
the first semiconductor chip and the second semiconductor chips mounted on the wiring board are sealed with a resin.

7. A semiconductor chip package according to claim 3, wherein
the second semiconductor chips and the wiring board each include a through electrode in a position facing the through electrode of the first semiconductor chip, and the plurality of through electrodes are electrically connected by the protruding electrode.

8. A method of manufacturing a semiconductor chip package, comprising the steps of:
aligning a first semiconductor chip including a protruding electrode with a wiring board including a wiring layer on a surface so that the protruding electrode is in contact with a predetermined connecting point on the wiring layer of the wiring board, and aligning one or two or more second semiconductor chips each including an protruding electrode with the first semiconductor chip so that the protruding electrodes are in contact with one another; and
establishing electrical connections between the protruding electrode of the first semiconductor chip and a connecting point of the wiring layer of the wiring board and between the protruding electrodes of the first semiconductor chip and the second semiconductor chips by a plating film, whereby a sufficient bonding strength can be obtained and electrical bonding can be sufficiently secured between the protruding electrodes.

9. A method of manufacturing a semiconductor chip package according to claim 8, wherein
the plating film is formed by electroplating or spray plating.

10. A method of manufacturing a semiconductor chip package according to claim 8, wherein
the plating film is formed while supersonic vibration is applied to a wall surface of a plating bath.

11. A method of manufacturing a semiconductor chip package according to claim 8, wherein
after a wiring board on which the first semiconductor chip and the second semiconductor chips are mounted is placed in a plating bath, and a pressure in the plating bath is reduced, a plating solution is contained in the plating bath.

12. A method of manufacturing a semiconductor chip package according to claim 8, wherein
the plating film is formed while applying a pressure to a plating solution contained in a plating bath.

13. A method of manufacturing a semiconductor chip package according to claim 8, further comprising the step of:
sealing the first semiconductor chip and the second semiconductor chips mounted on the wiring board with a resin after forming the plating film.

14. A semiconductor chip package according to claim 1,
wherein the plating film extends from a surface of the first semiconductor chip to a surface of the second semiconductor chips, covering at least a part of side surfaces of the protruding electrodes between the first and second semiconductor chips.

15. A method of manufacturing a semiconductor chip package according to claim 8,
wherein the plating film extends from a surface of the first semiconductor chip to a surface of the second semiconductor chips, covering at least a part of side surfaces of the protruding electrodes between the first and second semiconductor chips.

16. A semiconductor chip package according to claim 1,
wherein the plating film extends from a surface of the first semiconductor chip to a surface of the second semiconductor chips, covering the entire side surfaces of the protruding electrodes between the first and second semiconductor chips.

17. A method of manufacturing a semiconductor chip package according to claim 8,
wherein the plating film extends from a surface of the first semiconductor chip to a surface of the second semiconductor chips, covering the entire side surfaces of the protruding electrodes between the first and second semiconductor chips.
